(19) United States
(12) Patent Application Publication
(10) Pub. No.: US 2012/0025885 A1
(43) Pub. Date: Feb. 2, 2012

(54) MULTI-BIT INTERLACED LATCH

(76) Inventors: Kevin P. LAVERY, Sugar Land, TX (US); Robert C. Baumann, Dallas, TX (US); Badarish Mohan Subbannavar, Bangalore (IN)

(21) Appl. No.: 12/846,753

(22) Filed: Jul. 29, 2010

(51) Int. Cl. H03K 3/356

(52) U.S. Cl. 327/208

(57) ABSTRACT

A multi-bit interlace latch includes a first and second latch that each have redundant active feedback paths to reduce the incidence of soft-errors. The first and second latches have active circuitry that includes nodes that are susceptible to radiation-induced soft errors. Active circuitry from the second latch is interlaced between active circuitry of the first latch to increase the isolation between critical nodes of the first latch. While the second latch circuit increases isolation between critical nodes of the first latch, the first latch may also benefit the second latch by increasing the isolation between critical nodes of the first latch as well.

### BACKGROUND

Ever-decreasing feature sizes in electronics increases susceptibility to failures resulting from radiation associated with charged particles, high-energy neutrons, and thermal neutrons. Redundancy is used in various designs (such as in a master-slave flip-flop/latch design) reduces the likelihood of a radiation-induced change in the logic state of the designs. However, the added redundancy typically increases the size and topology of the design layout and relies on more widely separating critical nodes of a flip-flop. The node separation is also onerous because of the increases of the distances used to separate the critical nodes of the flip-flop, which typically results in larger flip-flop/latch sizes and increased manufacturing costs.

### SUMMARY

The problems noted above are solved in large part by isolating critical nodes of a latch using active feedback as disclosed herein. An illustrative embodiment comprises a multi-bit interlace latch that includes a first and second latch that each have redundant active feedback paths to reduce the incidence of soft-errors. The first and second latches have active circuitry that includes nodes that are susceptible to radiation-induced soft errors. Active circuitry from the second latch is interlaced between active circuitry of the first latch to increase the isolation between critical nodes of the first latch. While the second latch circuit increases isolation between critical nodes of the first latch, the first latch may also benefit the second latch by increasing the isolation between critical nodes of the first latch as well.

### BRIEF DESCRIPTION OF THE DRAWINGS

FIG. 1 shows an illustrative computing device 100 in accordance with embodiments of the disclosure.

FIG. 2 is a schematic diagram illustrating a multi-bit interlaced latch in accordance with embodiments of the disclosure.

FIG. 3 is a layout diagram illustrating a multi-bit interlaced latch in accordance with embodiments of the disclosure.

FIG. 4 is a layout diagram illustrating another multi-bit interlaced latch in accordance with embodiments of the disclosure.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Certain terms are used throughout the following description and claims to refer to particular system components. As one skilled in the art will appreciate, various names may be used to refer to a component. Accordingly, distinctions are not necessarily made herein between components that differ in name but not function. In the following discussion and in the claims, the terms “including” and “comprising” are used in an open-ended fashion, and thus are to be interpreted to mean “including, but not limited to . . . .” Also, the terms “coupled to” or “couples with” (and the like) are intended to describe either an indirect or direct electrical connection. Thus, if a first device couples to a second device, that connection may be through a direct electrical connection, or through an indirect electrical connection via other devices and connections.

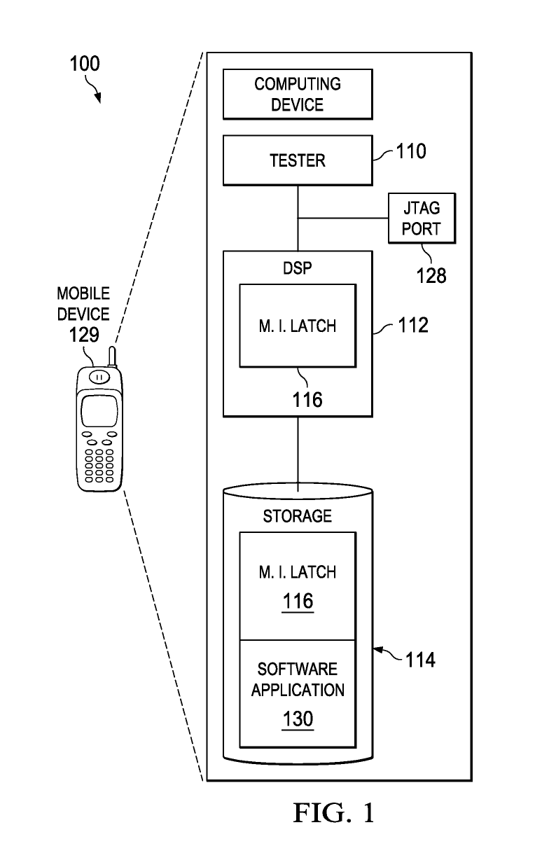

FIG. 1 shows an illustrative computing device 100 in accordance with embodiments of the disclosure. The computing device 100 may be, or may be incorporated into, a mobile communication device 129, such as a mobile phone, a personal digital assistant (e.g., a BLACKBERRY® device), a personal computer, or any other type of electronic system.

In some embodiments, the computing device 100 comprises a megacell or a system-on-chip (SoC) which includes control logic such as a digital signal processor (DSP) 112, a storage 114 (e.g., random access memory (RAM)) and tester 110. The storage 114 stores one or more software applications 130 (e.g., embedded applications) that, when executed by the DSP 112, perform any suitable function associated with the computing device 100. The tester 110 comprises logic that supports testing and debugging of the computing device 100 executing the software application 130. For example, the tester 110 may emulate a defective or unavailable component(s) of the computing device 100 so that a software developer may verify how the component(s), were it actually present on the computing device 100, would perform in various situations (e.g., how the component(s) would interact with the software application 130). In this way, the software application 130 may be debugged in an environment which resembles post-production operation.

The DSP 112 typically comprises memory and logic which store information frequently accessed from the storage 114. Various subsystems (such as the DSP 112 and the storage 114) of the computing device 100 may include multi-bit interlaced latches (e.g., M.I. Latches 116), which are used during the execution the software application 130. Errors can occur during the execution of the software application 130 that may negatively affect the results of the execution.

Soft-errors (such as changes in state of a logic device caused by radiation) often occur in circuits implemented in a common substrate. The circuits may include logic circuits (such as latches, flip-flops, and/or other memory devices) that rely upon feedback to maintain a logic state. The feedback signal may include actively driven signals as well as signals resulting from a stored capacitive charge. Disclosed herein are techniques for high efficiency of layouts that reduce the incidence of soft-errors by providing feedback from redundant circuits and interlacing circuitry between critical nodes.

For example, critical nodes can be interlaced within a single design cell of a multi-bit latch having a plurality of independent bits. Although a design cell is disclosed herein that includes two independent bits, other cells can be designed in accordance with the present disclosure that have, for example, three, four, eight, or 16 (and the like) bits. Interlacing critical nodes of such interlaced latch cells increases the separation of critical nodes and reduces the area penalty required for the node separation. The techniques may be employed, for example, in latches such as D-latches, flip-flops, monostable multivibrators, and the like. The design cell can be used by a design engineer, for example, when designing circuitry in which reduced susceptibility to soft-errors is desired, but without requiring the designer to know (and/or provide) implementation details of how the critical nodes are to be efficiently isolated.

Soft-error rates depend on the incidence of charged particles passing through material (such as devices formed within an integrated circuit). The charged particles interact primarily in regions of the electron shells of atoms because the electron orbitals primarily define an atomic radius for matter and thus the electrons tend to shield the nucleus. The mass difference between a nucleon (and/or charged particle) and an electron implies that the particle itself does not substantially deflect. Rather, the charged particle deflects electrons from their existing state/shell via a Coulomb force exerted by the charged particle. The work expended to influence electrons thus slows the incident charged particle and also displaces some electrons, which leaves a wake of charge separation.

The charge separation occurring in the wake of the charged particle tends to recombine in the structure in which the charge separation occurs. However, if the charge separation occurs in an volume (“critical volume”) where there is an external voltage gradient (such as found in certain structures and conditions in CMOS devices), the externally applied voltage gradient tends to sweep electrons towards the higher voltage. The nodes that collect charge receive a transient current pulse that results from the swept electrons or holes. The sweeping of separated charge into a node is self-limited, and the transient current may change the logical state of the node by overcoming the external voltage gradient. The Coulomb attraction between the separated charges tends to recombine these separated charges after the charges are formed. Accordingly, the pulse width of the transient current is typically limited by charge mobility.

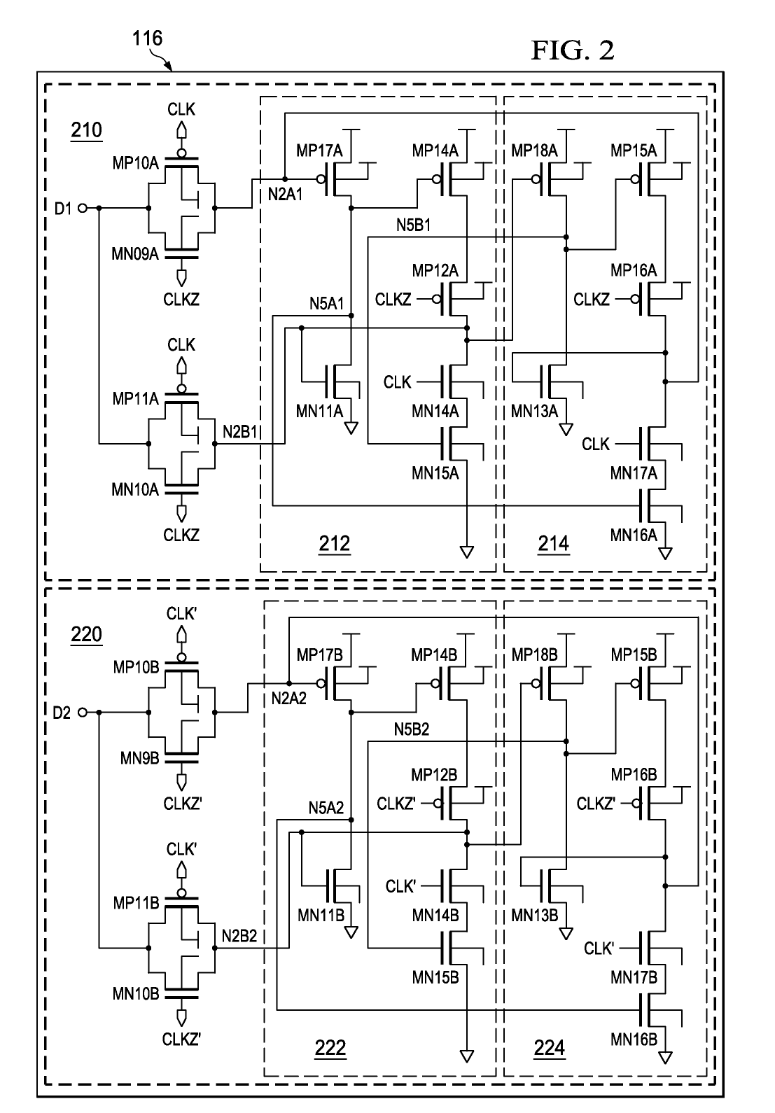

In CMOS devices, soft-errors can occur when separated charge is swept from a substrate (or well) to a drain of a transistor. For example, positive carriers (“holes”) of the separated charge can be swept towards the drain junction (from the n-well of) of a PMOS transistor having a source coupled to VCC and the drain that is presently in a low state. (See, in FIG. 2, for example, transistors MP17A/B and MP18A/B, which are susceptible to soft-errors when the drain nodes are in a low state.) PMOS transistors having a source coupled to VCC and a drain in a high state are not susceptible to soft-errors because no substantial voltage gradient exists.

Likewise, negative carriers (“electrons”) of the separated charge can be swept towards the drain junction (from the substrate of) of an NMOS transistor having a source coupled to VSS and the drain presently in a high state. (See, in FIG. 2, for example, transistors MN11A/B and MN13A/B, which are susceptible to soft-errors when the drain nodes are in a high state.) NMOS transistors having a source coupled to VSS and a drain in a low state are not susceptible to soft-errors because no substantial voltage gradient exists.

The susceptibility of a latch (for example) in an integrated circuit to soft-errors may be determined by the type of the radiation source and the relative locations of critical nodes of the latch to the induced charge separation. The charged particles in the silicon typically result from one of three radiation sources: alpha particles, thermal neutrons, and high-energy (e.g., cosmic) neutrons. Alpha particles (having a kinetic energy of around 10 MeV) typically have a relatively short range: such as around 8-10 cm in air, around 70-100 μm in silicon, and around 30 μm in copper. Accordingly, the source of the alpha particles would normally have to be relatively close to the silicon in order to cause soft-errors in a latch on the integrated circuit. Thus, separating critical nodes by a distance that is greater than the range of the alpha particles can substantially eliminate alpha particle-induced soft errors (whereas separating critical nodes by a distance that is around or even less than the range of the alpha particles in the substrate can also substantially reduce alpha particle-induced soft errors). An example of an alpha particle source that may affect integrated circuits is a package of the integrated circuit that may contain trace radioactive material.

Thermal neutrons may create charged particles by moving (recoil) or splitting (spallation) the nucleus of an atom in the substrate (or well) of the integrated circuit. Dopants used in integrated circuits typically contain atoms that are capable of absorbing thermal neutrons. For example, a relatively stable isotope of boron (the ¹⁰B isotope, which naturally occurs in around 20 percent of boron), can absorb thermal neutrons resulting in a nuclear fission reaction, which produces an alpha particle, a gamma ray, and a lithium ion. The products of the fission products may cause charge separation that induces soft-errors as discussed above. Depleted boron (which is substantially all ¹¹B) can be used to substantially reduce the incidence of thermal neutron-induced soft-error radiation. Soft-errors can also result from incident high-energy neutrons that are created when charged particles from the cosmic background interact with the earth's atmosphere.

FIG. 2 is a schematic diagram illustrating a multi-bit interlaced latch in accordance with embodiments of the disclosure. Multi-bit interlaced latch 116 is illustrated as including latch 210 and latch 220, although more latches may be interlaced within multi-bit interlaced latch 116. Control signals such as CLK and CLKZ in latch 210 may be the same signals as CLK′ and CLKZ′ in latch 220 to provide synchronous operation of each latch (with each bit holding independent data), or may be different to allow for asynchronous operation of the latches 210 and 220. Signals CLK and CLKZ are used to latch signal D1 in latch 210 (via transistors MP10A, MN09A, MP11A, and MN10A) and signals CLK′ and CLKZ′ are used to latch signal D2 in latch 220 (via transistors MP10B, MN09B, MP11B, and MN10B). Transistors MP10A, MN09A, MP11A, and MN10A are paired to form transfer gates that are used to drive signal D1 at nodes N2A1 and N2B1 (respectively), and transistors MP10B, MN09B, MP11B, and MN10B are paired to form transfer gates that are used to drive signal D2 at nodes N2A2 and N2B2. Each latch (210 and 220) stores data using redundant inverters (such as the cross-coupled inverter of each stage 212 and 214 of latch 210 and of each stage 222 and 224 of latch 220). Multi-bit interlaced latch 116 thus maintains a given data state at nodes N2A1 and N2A2 through active feedback.

As indicated above for latch 210, critical nodes exist at the drains of transistors MP17A, MN14A, MN15A, MP18A, MN17A, and MN16A or the drains of transistors MN11A, MP14A, MP12A, MN13A, MP15A, and MP16A, depending on how the transistors are biased (see below). Stage 212 of latch 210 includes two inverters (formed by transistors MP17A and MN11A and by transistors MP14A, MP12A, MN14A, and MN15A, respectively) that are (in conjunction with stage 214) cross-coupled to store data. Because a soft-error may disturb the stored-data-state of the latch, a second redundant stage 214 of latch 210 is provided that includes two additional inverters (formed by transistors MP18A and MN13A and by transistors MP15A, MP16A, MN17A, and MN16A respectively).

Without the redundant stage, a current pulse caused by a charged particle that disturbed the input to only one inverter would cause the output—and the input to the next inverter—to “flip” states: the flipped state will be latched if the current-pulse persists long enough for the positive feedback to propagate and latch the error. The redundant architecture of the latch helps to ensure that the latch will not flip to a charged particle disturbance at a single critical node.

With respect to latch 220, critical nodes exist at the drains of transistors MP17B, MN14B, MN15B, MP18B, MN17B, and MN16B or the drains of transistors MN11B, MP14B, MP12B, MN13B, MP15B, and MP16B, depending on how the transistors are biased (see below). Stage 222 includes two inverters (formed by transistors MP17B and MN11B and by transistors MP14B, MP12B, MN14B, and MN15B, respectively) that are cross-coupled to store data. Because a soft-error may disturb the stored-data-state of the latch, a second redundant stage 224 is provided that includes two additional inverters (formed by transistors MP18B and MN13B and by transistors MP15B, MP16B, MN17B, and MN16B respectively).

Referring again to latch 210, the latch 210 may have the nodes N2A1 and N2B1 set to a state “1” (e.g., high) with nodes N5A1 and N5B1 set to a state “0” (e.g., low). In this configuration, the drains of transistors MP17A, MN14A, MN15A, MP18A, MN17A, and MN16A are biased so that they are susceptible to soft-errors. When nodes N2A1 and N2B1 are set to a state “0” with nodes N5A1 and N5B1 set to a state “1,” the drains of transistors MN11A, MP14A MP12A, MN13A, MP15A, MP16A are biased so that they are susceptible to soft-errors. Because of the redundancy, a single soft-error at a single critical node is less likely to cause a change in the state of the latch 210. However, the redundant topology can fail when multiple nodes flip at the same time (e.g., MP17A and MP18A). Thus if the node at the drain of MP17A flips as a result of a charged particle disturbance, a disturbance (including all disturbances caused by a single cosmic neutron, for example) at any one (or possibly more) of the other critical nodes (at the drains of MN14A, MN15A, MP18A, MN16A and MN17A) would normally cause the latch 210 to flip states.

Likewise, latch 220 may have the nodes N2A2 and N2B2 set to a state “1” (e.g., high) with nodes N5A2 and N5B2 set to a state “0” (e.g., low). In this configuration, the drains of transistors MP17B, MN14B, MN15B, MP18B. MN17B, and MN16B are biased so that they are susceptible to soft-errors. When nodes N2A2 and N2B2 are set to a state “0” with nodes N5A2 and N5B2 set to a state “1,” the drains of transistors MN11B, MP14B MP12B, MN13B, MP15B, MP16B are biased so that they are susceptible to soft-errors. Because of the redundancy, a single soft-error at a single critical node is less likely to cause a change in the state of the latch 220. However, the redundant topology can fail when multiple nodes flip at the same time (e.g. MP17B and MP18B). Thus if the node at the drain of MP17B flips as a result of a charged particle disturbance, a disturbance (including disturbances caused by a single event) at any one (or possibly more) of the other critical nodes (at the drains of MN14B, MN15B, MP18B, MN16B and MN17B) would normally cause the latch 220 to flip states.

Because simultaneous disturbances of the critical nodes can cause a soft-error to be latched, the nodes can be separated from each other in the physical layout (as discussed in the following figures) to help prevent a single disturbance from affecting multiple critical nodes (which might then be latched).

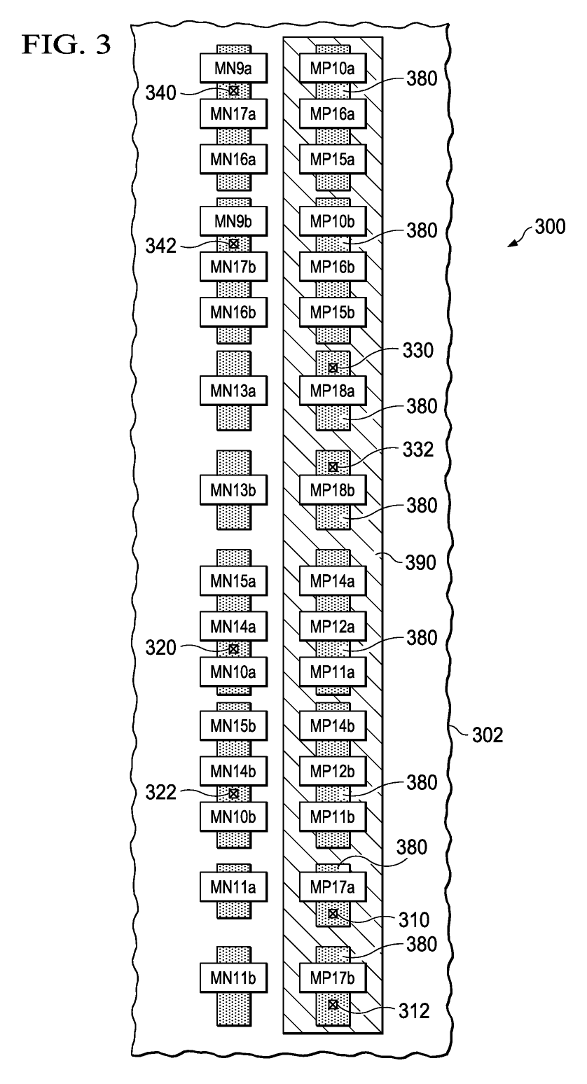

FIG. 3 is a layout diagram illustrating a multi-bit interlaced latch in accordance with embodiments of the disclosure. Layout 300 is an embodiment of latch 200 and includes an n-well 390 formed in a p-type substrate 302 of an integrated circuit that includes the latch 200. Doped silicon regions that are coupled by at least one transistor gate form transistor structures 380 where the gates typically overlap adjacent areas of doped silicon. (For clarity, not all transistor structures 380 have been individually labeled.) The transistor structures 380 are formed by adjacent doped silicon regions that are coupled together by at least one transistor gate that controls electrical communication (such as current) between the adjacent doped silicon regions. For example, a transistor structure 380 (associated with contact 340) is a three-transistor structure (including transistors MN9A, MN17A, and MN16A) having a common node that is driven by the three transistors of the transistor structure 380. Contact 340 illustrates a location, for example, at which node N2A1 is driven by the “NMOS-side” transistors. In another example, a transistor structure 380 may include a single transistor MP18A having a drain over which contact 330 is laid.

The locations for critical nodes for latch 210 are illustrated as follows. For example, node N2A1 is driven by the drain of transistor MN17A over which contact 340 is placed (the node N2A1 is also driven by the PMOS structure directly above). Node N2B1 is driven by the drain of transistor MN14A over which contact 320 is placed (the node N2B1 is also driven by the PMOS structure directly above). Node N5A1 is driven by the drain of transistor MP17A over which contact 310 is placed. Node N5B1 is driven by the drain of transistor MP18A over which contact 330 is placed.

Thus, it can be seen that the critical nodes for latch 210 are widely spaced within the area allowed for the multi-bit interlaced latch 200 so as to substantially reduce the opportunity for a single charged particle event to flip two or more of the critical nodes of the dual-redundant latch 210. (A substantial reduction can be defined as a 50 percent decrease of a soft-error occurring.) Further, it can be seen that active circuitry for latch 220 is interlaced between the critical nodes of 210. As discussed below, critical nodes of (the also dual-redundant) latch 220 are interlaced between the critical nodes of latch 210, which further reduces soft-errors because critical nodes of the other latch (e.g., latch 220) separate critical nodes of the same latch (e.g., latch 210).

The locations for critical nodes for latch 220 are illustrated as follows. For example, node N2A2 is driven by the drain of transistor MN17B over which contact 342 is placed (the node N2A2 is also driven by the PMOS structure directly above). Node N2B2 is driven by the drain of transistor MN14B over which contact 322 is placed (the node N2B2 is also driven by the PMOS structure directly above). Node N5A2 driven by the drain of transistor MP17B over which contact 312 is placed. Node N5B2 is driven by the drain of transistor MP18B over which contact 332 is placed.

Thus, it can be seen that the critical nodes for latch 220 are widely spaced within the area allowed for the multi-bit interlaced latch 200 so as to substantially reduce the opportunity for a single charged particle event to flip two or more of the critical nodes of the dual-redundant latch 220. Further, it can be seen that active circuitry for latch 210 is interlaced between the critical nodes of 220. As discussed above, critical nodes of (the also dual-redundant) latch 210 are interlaced between the critical nodes of latch 220, which further reduces soft-errors because critical nodes of the other latch (e.g., latch 210) separate critical node of the same latch (e.g., latch 220).

As illustrated in FIG. 3, the critical nodes of latch 210 are separated by interlacing active circuitry of latch 220 (including circuitry that contains critical nodes of latch 220), and the critical nodes of latch 210 are separated by interlacing active circuitry of latch 220 (including circuitry that contains critical nodes of latch 220). Thus, the illustrated layout demonstrates a synergistic benefit of reducing the incidence of soft-errors, while minimizing the area that is needed to lay out the latches 210 and 220 having increased resistance to susceptibility of soft-errors.

The interlacing of active circuitry of each of latches 210 and 220 is performed so that at each latch has a similar layout (which helps to equalize performance characteristics between each latch on a multi-bit interlaced latch 116, for example). As illustrated, transistor structures 380 (which may include one or more transistors, for example) of each latch are laid out in a similar fashion. For example, each transistor structure 380 from latch 210 has an adjacent transistor structure 380 from latch 220, wherein the adjacent transistor structure 380 from the latch 220 performs a similar function as the function of the transistor structure 380 from the latch 210. (A similar function may be demonstrated by substantial similarities in the physical structure of the embodiment or in the schematic diagram of the transistor structure 380, for example.) Thus, any two of transistor structures 380 (having a critical node, for example) from latch 210 are physically separated by at least one transistor structure 380 from latch 220.

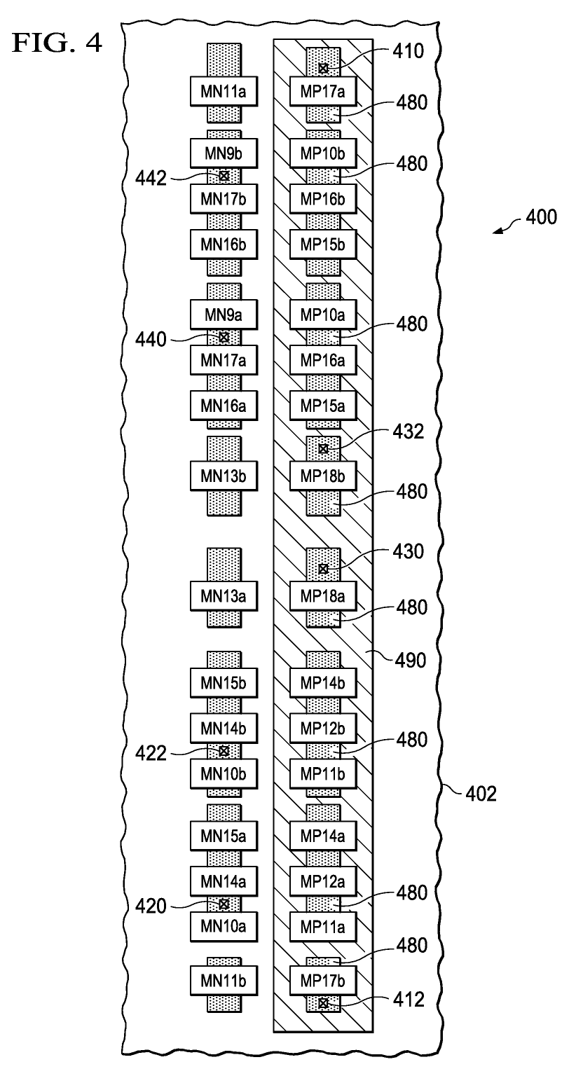

FIG. 4 is a layout diagram illustrating another multi-bit interlaced latch in accordance with embodiments of the disclosure. Layout 400 is another embodiment of latch 200 and includes an n-well 490 formed in a p-type substrate 402 of an integrated circuit that includes the latch 200. Doped silicon regions that are coupled by at least one transistor gate form transistor structures 480 where the gates typically overlap adjacent areas of doped silicon. (For clarity, not all transistor structures 480 have been individually labeled.) The transistor structures 480 are formed by adjacent doped silicon regions that are coupled together by at least one transistor gate that controls electrical communication between the adjacent doped silicon regions. For example, a transistor structure 480 (associated with contact 440) is a three-transistor structure (including transistors MN9A, MN17A, and MN16A) having a common node that is driven by the three transistors of the transistor structure 480. Contact 440 illustrates a location, for example, at which node N2A1 is driven by the “NMOS-side” transistors. In another example, a transistor structure 480 may include a single transistor MP18A having a drain over which contact 430 is laid.

The locations for critical nodes for latch 210 are illustrated as follows. For example, node N2A1 is driven by the drain of transistor MN17A over which contact 440 is placed. Node N2B1 is driven by the drain of transistor MN14A over which contact 420 is placed. Node N5A1 driven by the drain of transistor MP17A over which contact 410 is placed. Node N5B1 is driven by the drain of transistor MP18A over which contact 430 is placed. As shown in FIG. 4, NMOS and PMOS transistors that drive a common node are located adjacent to each other according to spacing and timing requirements (for example transistors MP17A and MN11A both drive node N5A1).

Thus, it can be seen that the critical nodes for latch 210 are widely spaced within the area allowed for the multi-bit interlaced latch 200 so as to substantially reduce the opportunity for a single charged particle event to flip two or more of the critical nodes of the dual-redundant latch 210. Further, it can be seen that active circuitry for latch 220 is interlaced between the critical nodes of 210. As discussed below, critical nodes of (the also dual-redundant) latch 220 are interlaced between the critical nodes of latch 210, which further reduces soft-errors because critical nodes of the latch 220 separate critical node of the latch 210.

The locations for critical nodes for latch 220 are illustrated as follows. For example, node N2A2 is driven by the drain of transistor MN17B over which contact 442 is placed. Node N2B2 is driven by the drain of transistor MN14B over which contact 422 is placed. Node N5A2 driven by the drain of transistor MP17B over which contact 412 is placed. Node N5B2 is driven by the drain of transistor MP18A over which contact 432 is placed.

Thus, it can be seen that the critical nodes for latch 220 are widely spaced within the area allowed for the multi-bit interlaced latch 200 so as to substantially reduce the opportunity for a single charged particle event to flip two or more of the four critical nodes of the dual-redundant latch 220. Further, it can be seen that active circuitry for latch 210 is interlaced between the critical nodes of 220. As discussed above, critical nodes of (the also dual-redundant) latch 210 are interlaced between the critical nodes of latch 220, which further reduces soft-errors because critical nodes of the latch 210 work to sweep away carriers that might otherwise propagate to a critical node of the latch 220.

As illustrated in FIG. 4, the critical nodes of latch 210 are separated by interlacing active circuitry of latch 220 (including circuitry that contains critical nodes of latch 220), and the critical nodes of latch 210 are separated by interlacing active circuitry of latch 220 (including circuitry that contains critical nodes of latch 220). Thus, the illustrated layout demonstrates a synergistic benefit of reducing the incidence of soft-errors, while minimizing the area that is needed to lay out the latches 210 and 220 having increased susceptibility of to soft-errors.

The interlacing of active circuitry of each of latches 210 and 220 is performed so that at each latch has a similar layout (which helps to equalize performance characteristics between each latch on a multi-bit interlaced latch 116, for example). As illustrated, transistor structures 480 (which may include one or more transistors, for example) of each latch are laid out in a similar fashion, except that the transistor structures 480 are laid out in reverse order in the cell. (A similar function may be demonstrated by substantial similarities in the physical structure of the embodiment or in the schematic diagram of the transistor structure 480, for example.) For example, each transistor structure 480 from latch 210 is laid out in an order that is opposite (a mirror image, for example) the order in which each similar transistor structure 480 from latch 220 is laid out, wherein the each similar transistor structure 480 from the latch 220 performs a similar function as the function of a corresponding transistor structure 480 from the latch 210. Thus, any two blocks of circuitry (having a critical node, for example) from latch 210 are physically separated by at least one block of circuitry from latch 220.

What is claimed is:

1. A circuit for latching logic states, comprising:
a first latch disposed in a substrate, the first latch having a first critical node coupled to a drain of a first transistor driving a first feedback path, a second critical node coupled to a drain of a second transistor driving a second feedback path, a third critical node coupled to a drain of a third transistor driving a third feedback path, and a fourth critical node coupled to a drain of a fourth transistor driving a third feedback path, each feedback path of the first latch being driven independently of each other when the first latch is in a latched state;
a second latch disposed in the substrate, the second latch having a first critical node coupled to a drain of a transistor driving a first feedback path, a second critical node coupled to a drain of a second transistor driving a second feedback path, a third critical node coupled to a drain of a third transistor driving a third feedback path, and a fourth critical node coupled to a drain of a fourth transistor driving a fourth feedback path, each feedback path of the second latch being driven independently of each other when the second latch is in a latched state, wherein the second latch has interlaced active circuitry that is disposed in the substrate between at least two of the drains of the first, second, third, and fourth transistors of the first latch.

2. The circuit of claim 1, wherein the interlaced active circuitry of the second latch comprises at least one of the drains of the first, second, third, and fourth transistors of the second latch.

3. The circuit of claim 1, wherein the first and second feedback paths of the first latch are coupled to a logic input of the first latch, and wherein the first and second feedback paths of the second latch are coupled to a logic input of the second latch, wherein the logic inputs of the first and second latch are configured to store logic states that are the same or different.

4. The circuit of claim 1, wherein a first and second transfer gate of the first latch are coupled respectively between each of the first and second feedback paths of the first latch and a logic input of the first latch, and a first and second transfer gate of the second latch are coupled respectively between each of the first and second feedback paths of the second latch and a logic input of the second latch.

5. The circuit of claim 4, wherein the first and second transfer gate of the first latch are clocked with a first latch clock signal to latch the logic input of the first latch, and the first and second transfer gate of the second latch are clocked with a second latch clock signal to latch the a logic input of the second latch.

6. The circuit of claim 5, wherein the first latch clock signal and the second latch clock signal are configured to operate synchronously.

7. The circuit of claim 5, wherein the first latch clock signal and the second latch clock signal are configured to operate asynchronously.

8. The circuit of claim 1, wherein the first feedback path of the first latch is coupled to a control gate of the transistor driving the third feedback path of the first latch, wherein the second feedback path of the first latch is coupled to a control gate of the transistor driving the fourth feedback path of the first latch, wherein the third feedback path of the first latch is coupled to a control gate of the transistor driving the first feedback path of the first latch, and wherein the fourth feedback path of the first latch is coupled to a control gate of the transistor driving the second feedback path of the first latch.

9. The circuit of claim 1, wherein the first critical node of the first latch is susceptible to soft-errors when the drain of the transistor driving the first critical node of the first latch is at a high logic state and the source of the transistor driving the first critical node of the first latch is at a high voltage level, wherein the second critical node of the first latch is susceptible to soft-errors when the drain of the transistor driving the second critical node of the first latch is at a high logic state and the source of the transistor driving the second critical node of the first latch is at a high voltage level, wherein the third critical node of the first latch is susceptible to soft-errors when the drain of the transistor driving the third critical node of the first latch is at a low logic state and the source of the transistor driving the third critical node of the first latch is at a high voltage level, and wherein the fourth critical node of the first latch is susceptible to soft-errors when the drain of the transistor driving the fourth critical node of the first latch is at a low logic state and the source of the transistor driving the fourth critical node of the first latch is at a high voltage level.

10. The circuit of claim 1, wherein the interlaced active circuitry of the second latch that is disposed in the substrate between at least two of the drains of the first, second, third, and fourth transistors of the first latch includes a transistor structure that is formed by adjacent doped silicon regions that are coupled together by at least one transistor gate that controls electrical communication between the adjacent doped silicon regions.

11. The circuit of claim 10, wherein each transistor structure from the first latch is adjacent to an adjacent transistor structure from the second latch, wherein the adjacent transistor structure from the second latch performs a similar function to the function of the associated transistor structure from the first latch.

12. The circuit of claim 10, wherein each transistor structure from the first latch is laid out in a first order of a first direction, and wherein each transistor structure from the second latch is laid out in a second order that is a mirror image to the first order.

13. A digital system, comprising:
a memory including a first latch disposed in a substrate, the first latch having a drain of a first transistor driving a first feedback path, a drain of a second transistor driving a second feedback path, a third transistor driving a third feedback path, and a fourth transistor driving a third feedback path, and including a second latch disposed in the substrate, the second latch having a drain of a first transistor driving a first feedback path, a drain of a second transistor driving a second feedback path, a drain of a third transistor driving a third feedback path, and a drain of a fourth transistor driving a fourth feedback path, wherein the second latch has interlaced active circuitry that is disposed in the substrate between at least two of the drains of the first, second, third, and fourth transistors of the first latch.

14. The system of claim 13 further comprising:
a processor including a first latch disposed in the substrate, the first latch having a drain of a first transistor driving a first feedback path, a drain of a second transistor driving a second feedback path, a third transistor driving a third feedback path, and a fourth transistor driving a third feedback path, and including a second latch disposed in the substrate, the second latch having a drain of a first transistor driving a first feedback path, a drain of a second transistor driving a second feedback path, a drain of a third transistor driving a third feedback path, and a drain of a fourth transistor driving a fourth feedback path, wherein the second latch has interlaced active circuitry that is disposed in the substrate between at least two of the drains of the first, second, third, and fourth transistors of the first latch, wherein the first and second latches of the processor are respectively logically coupled to the first and second latches of the memory.

15. A method for decreasing susceptibility to soft-errors of circuits using active feedback, comprising:
forming a first latch in a substrate, the first latch having a drain of a first transistor driving a first feedback path, a drain of a second transistor driving a second feedback path, a third transistor driving a third feedback path, and a fourth transistor driving a third feedback path;
forming a second latch in the substrate, the second latch having a drain of a first transistor driving a first feedback path, a drain of a second transistor driving a second feedback path, a drain of a third transistor driving a third feedback path, and a drain of a fourth transistor driving a fourth feedback path, wherein the second latch is formed having interlaced active circuitry that is disposed in the substrate between at least two of the drains of the first, second, third, and fourth transistors of the first latch.

16. The method of claim 15, wherein each feedback path of the first latch and second latch are formed so that each feedback path is driven independently of each other feedback path when the first and second latches are in a latched state.

18. The method of claim 15, wherein the interlaced active circuitry of the second latch that is formed in the substrate between at least two of the drains of the first, second, third, and fourth transistors of the first latch is formed using a transistor structure that is having adjacent doped silicon regions that are coupled together by at least one transistor gate arranged to control electrical communication between the adjacent doped silicon regions.

19. The method of claim 18, wherein each transistor structure from the first latch is formed adjacent to an adjacent transistor structure from the second latch, wherein the adjacent transistor structure from the second latch is structured to perform a similar function to the function of the associated transistor structure from the first latch.

20. The method of claim 18, wherein each transistor structure from the first latch is formed using a first order of a first direction, and wherein each transistor structure from the second latch is formed using a second order that is a mirror image to the first order.
